(19) United States
(12) Patent Application Publication
(10) Pub. No.: US 2019/0265537 A1
(43) Pub. Date: Aug. 29, 2019

(54) DISPLAY DEVICE

(71) Applicants: HKC Corporation Limited, Shenzhen (CN); Chongqing HKC Optoelectronics Technology Co., Ltd., Chongqing (CN)

(72) Inventor: Wei Fu, Shenzhen (CN)

(21) Appl. No.: 16/255,820

(22) Filed: Jan. 24, 2019

Related U.S. Application Data
(63) Continuation of application No. PCT/CN2018/118900, filed on Dec. 3, 2018.

(30) Foreign Application Priority Data
Feb. 24, 2018 (CN) 201820270919.6

(51) Int. Cl. G02F 1/1345; H01R 12/79; G02F 1/133; H05K 1/02; H05K 1/14; H05K 1/18

(52) U.S. Cl. CPC G02F 1/13452; H01R 12/79; G02F 1/13306; H05K 1/0259; H05K 2201/0746; H05K 1/189; H05K 2201/10136; H05K 2201/10174; H05K 2201/10356; H05K 1/147

(57) ABSTRACT

The present disclosure provides a display device which includes a display panel, a connecting circuit board, a composite circuit board, and flexible circuit units, an absolute value of a difference between the maximum thickness of the connecting circuit board and the maximum thickness of the composite circuit board is less than or equal to a first preset thickness.

### CROSS-REFERENCE TO RELATED PRESENT DISCLOSURES

The present application is a Continuation Application of PCT Application No. PCT/CN2018/118900, filed Dec. 3, 2018, which claims the benefit of Chinese Patent Application No. 201820270919.6, filed Feb. 24, 2018, with the State Intellectual Property Office and entitled “display device”, the entirety of which is hereby incorporated herein by reference.

### TECHNICAL FIELD

The present disclosure generally relates to the technical field of display, and more particularly relates to a display device.

### BACKGROUND

In order to drive the display panel to operate normally, the display device is provided with flexible circuit units, a composite circuit board, and a connecting circuit board, the flexible circuit unit and the control circuit on the composite circuit board work together to drive the display panel to display normally, and the connecting circuit on the composite circuit board and the connecting circuit board are configured to realize at least partial electrical connection in the display device. Because the circuit on the composite circuit board is usually more complex than the circuit on the connecting circuit board, specifically, the composite circuit board normally includes electronic components such as inductor and integrated circuit chip, etc., while the connecting circuit board is usually only provided with resistor and capacitors, etc., resulting that the composite circuit board is thicker than the connecting circuit board. For example, the thickness of the composite circuit board is usually about 4 millimeters, while the thickness of the connecting circuit board is only about 2 millimeters. In the process of packing and transporting the display devices, the display devices are usually stacked along the normal direction of a panel surface of the display panel to save space and reduce the packing and transportation costs. However, due to the difference in thickness between the composite circuit board and the connecting circuit board, there is a lack of support for the flexible circuit unit connected between the display panel and the connecting circuit board, especially in the transportation process, the suspended flexible circuit unit is prone to peel off under the action of an external force and separate from the display panel, resulting in a decrease in the reliability of the display device.

### SUMMARY

It is therefore one main object of the disclosure to provide a display device, which aims to solve the technical problem that the flexible circuit unit is prone to peel off, and to improve the reliability of the display device.

In order to realize the above aim, the display device provided by the present disclosure includes a display panel, a connecting circuit board, a composite circuit board, and flexible circuit units, the connecting circuit board is defined along an extending direction of a board surface of the display panel, and the connecting circuit board includes a main body and a transient suppression diode defined on the main body. The composite circuit board is defined along the extending direction of the board surface of the display panel. And at least a part of the flexible circuit units connect between the display panel and the main body, and at least another part of the flexible circuit units connect between the display panel and the composite circuit board. An absolute value of a difference between the maximum thickness of the connecting circuit board and the maximum thickness of the composite circuit board is less than or equal to a first preset thickness.

Optionally, a positive electrode of the transient suppression diode connects to a ground line of the display device, and a negative electrode of the transient suppression diode connects to a positive power line of the display device; or a positive electrode of the transient suppression diode connects to a negative power line of the display device, and a negative electrode of the transient suppression diode connects to a ground line of the display device.

Optionally, an end of the transient suppression diode away from the main body includes a support surface, the support surface is parallel to the board surface of the connecting circuit board.

Optionally, the first preset thickness is less than or equal to 0.2 millimeters.

Optionally, an absolute value of a difference between the maximum thickness of the display panel and the maximum thickness of the connecting circuit board is less than or equal to a second preset thickness; and an absolute value of a difference between the maximum thickness of the display panel and the maximum thickness of the composite circuit board is less than or equal to a third preset thickness.

Optionally, the second preset thickness is less than or equal to 0.5 millimeters, and the third preset thickness is less than or equal to 0.5 millimeters.

Optionally, the transient suppression diode is defined at the center of the connecting circuit board.

Optionally, the connecting circuit board includes at least two transient suppression diodes, the transient suppression diodes are dispersedly defined on the connecting circuit board.

Optionally, the display panel includes a first substrate, a second substrate, and liquid crystals filled between the first substrate and the second substrate; the flexible circuit unit includes a liquid crystal deflection control circuit; the composite circuit board includes a timing control circuit; the display device further includes a flat cable, and the flat cable connects between the connecting circuit board and the composite circuit board.

The present disclosure also provides a display device, the display device includes a display panel, a connecting circuit board, a composite circuit board, and flexible circuit units, the connecting circuit board is defined along an extending direction of a board surface of the display panel, and the connecting circuit board includes a main body and a transient suppression diode defined on the main body, a positive electrode of the transient suppression diode connects to a ground line of the display device, and a negative electrode of the transient suppression diode connects to a positive power line of the display device; or a positive electrode of the transient suppression diode connects to a negative power line of the display device, and a negative electrode of the transient suppression diode connects to a ground line of the display device, an end of the transient suppression diode away from the main body includes a support surface, the support surface is parallel to the board surface of the connecting circuit board. The composite circuit board is defined along the extending direction of the board surface of the display panel. At least a part of the flexible circuit units connect between the display panel and the main body, and at least another part of the flexible circuit units connect between the display panel and the composite circuit board. An absolute value of a difference between the maximum thickness of the connecting circuit board and the maximum thickness of the composite circuit board is less than or equal to a first preset thickness, an absolute value of a difference between the maximum thickness of the display panel and the maximum thickness of the connecting circuit board is less than or equal to a second preset thickness; and an absolute value of a difference between the maximum thickness of the display panel and the maximum thickness of the composite circuit board is less than or equal to a third preset thickness.

In the technical solution of the present disclosure, the display device includes a display panel, a connecting circuit board, a composite circuit board, and flexible circuit units, the connecting circuit board is defined along the extending direction of the board surface of the display panel, and the connecting circuit board includes the main body and the transient suppression diode defined on the main body. The composite circuit board is also defined along the extending direction of the board surface of the display panel. At least a part of the flexible circuit units connect between the display panel and the main body, and at least another part of the flexible circuit units connect between the display panel and the composite circuit board. The absolute value of the difference between the maximum thickness of the connecting circuit board and the maximum thickness of the composite circuit board is less than or equal to the first preset thickness. The flexible circuit unit and the control circuit defined on the composite circuit board work together to drive the display panel to normally display, and the connection circuit on the composite circuit board and the connecting circuit board are configured to realize at least partial electrical connection in the display device. On the one hand, the transient suppression diode increases the thickness of the connecting circuit board, so that the absolute value of the difference between the maximum thickness of the connecting circuit board and the maximum thickness of the composite circuit board is less than or equal to the first preset thickness, Furthermore, the height difference between the flexible circuit unit connected between the display panel and the main body and the flexible circuit unit connected between the display panel and the composite circuit board during boxing is reduced, so that the display panel, the connecting circuit board, and the composite circuit board respectively provide support for the corresponding flexible circuit units, thereby avoiding peeling of the flexible circuit unit from the display panel and improving the reliability of the display device.

### BRIEF DESCRIPTION OF THE DRAWINGS

To better illustrate the technical solutions that are reflected in various embodiments according to this disclosure or that are found in the prior art, the accompanying drawings intended for the description of the embodiments herein or for the prior art may now be briefly described, it is evident that the accompanying drawings listed in the following description show merely some embodiments according to this disclosure, and that those having ordinary skill in the art may be able to obtain other drawings based on the arrangements shown in these drawings without making inventive efforts.

FIG. 1 is a structural diagram of the display device of the present disclosure according to some embodiments;

FIG. 2 is a cross-sectional diagram of the display device shown in FIG. 1 along line A-A;

FIG. 3 is a circuit connection diagram of the transient suppression diode of the display device of the present disclosure according to some embodiments;

FIG. 4 is a circuit connection diagram of the transient suppression diode of the display device of the present disclosure according to another embodiments.

The realization of the aim, functional characteristics, advantages of the present disclosure are further described specifically with reference to the accompanying drawings and embodiments.

### DETAILED DESCRIPTION

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present invention without creative efforts shall fall within the protection scope of the present invention.

It is to be understood that, all of the directional instructions in the exemplary embodiments of the present disclosure (such as top, down, left, right, front, back . . . ) can only be used for explaining relative position relations, moving condition of the elements under a special form (referring to figures), and so on, if the special form changes, the directional instructions changes accordingly.

In addition, the descriptions, such as the “first”, the “second” in the exemplary embodiment of present disclosure, can only be used for describing the aim of description, and cannot be understood as indicating or suggesting relative importance or impliedly indicating the number of the indicated technical character. Therefore, the character indicated by the “first”, the “second” can express or impliedly include at least one character. In addition, the technical proposal of each exemplary embodiment can be combined with each other, however the technical proposal must base on that the ordinary skill in that art can realize the technical proposal, when the combination of the technical proposals occurs contradiction or cannot realize, it should consider that the combination of the technical proposals does not existed, and is not contained in the protection scope required by the present disclosure.

The present disclosure provides a display device.

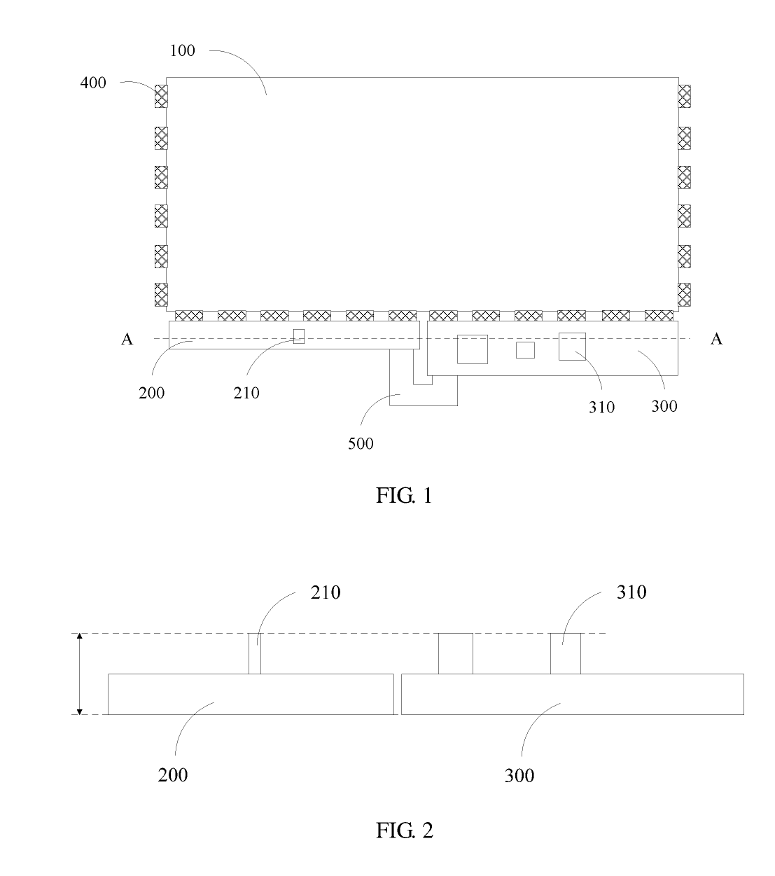

In the embodiments of the present disclosure, as shown in FIGS. 1 and 2, the display device includes a display panel 100, a connecting circuit board 200, a composite circuit board 300, and flexible circuit units 400, the connecting circuit board 200 is defined along the extending direction of the board surface of the display panel 100, and the connecting circuit board 200 includes a main body and a transient suppression diode 210 defined on the main body. The composite circuit board 300 is defined along the extending direction of the board surface of the display panel 100. At least one portion of the flexible circuit unit 400 connects between the display panel 100 and the main body, and at least another part of the flexible circuit units 400 connect between the display panel 100 and the composite circuit board 300. The absolute value of the difference between the maximum thickness of the connecting circuit board 200 and the maximum thickness of the composite circuit board 300 is less than or equal to the first preset thickness.

Specifically, the display panel 100 may be, for example, an LCD display panel, an OLED display panel, a QLED display panel, a curved display panel, or other display panel for displaying images. The connecting circuit board 200 and the composite circuit board 300 are both defined along the extending direction of the board surface of the display panel 100, i.e. the board surface direction of the connecting circuit board 200 and the board surface direction of the display panel 100 are substantially on the same plane, and the board surface direction of the composite circuit board 300 and the board surface direction of the display panel 100 are also substantially on the same plane. Furthermore, by aligning the top planes, the bottom planes, or the center planes of the display panel 100, the connecting circuit board 200, and the composite circuit board 300, the difference in thickness direction of the entire display device can be reduced, so that when a plurality of display devices are stacked along the normal direction of the board surface of the display panel 100, the support of each display device reaches a relatively stable state. The connecting circuit board 200 includes a main body and a transient suppression diode 210 defined on the main body, the main body is provided with components, such as a resistor, a capacitor, etc., for realizing at least a part of the electrical connection of the display device, and the transient suppression diode 210 is used as an external component protruding relative to the main body of the connecting circuit board 200, thereby increasing the maximum thickness of the connecting circuit board 200. The composite circuit board 300 can be regarded as a combination of the conventional timing control board and the connecting circuit board to reduce the cost of the display device, i.e., the composite circuit board 300 is provided with the timing control circuit. In the timing control circuit, components such as external integrated circuit chips 310 and inductors are usually included in the timing control circuit, resulting that the composite circuit board 300 is thicker than the main body connecting with the circuit board 200. The flexible circuit unit 400 (such as a chip on film, abbreviated as COF) is a control circuit defined on a flexible substrate, and electrically connected to the display panel 100, and the flexible circuit unit 400 controls the display of the display panel 100 together with the timing control circuit on the composite circuit board 300. In the display device, there are usually a plurality of COFs, at least a part of which connect between the display panel 100 and the main body of the connecting circuit board 200, and at least another part of which connect between the display panel 100 and the composite circuit board 300 to respectively realize corresponding circuit functions. On the one hand, the transient suppression diode 210 on the connecting circuit board 200 increases the maximum thickness of the connecting circuit board 200, so that the absolute value of the difference between the maximum thickness of the connecting circuit board 200 and the maximum thickness of the composite circuit board 300 is less than or equal to the first preset thickness, then when the display devices are stacked, even if the number of stacked display devices is large, the main body of the upper connecting circuit board 200 abuts the transient suppression diode 210 of the lower connecting circuit board 200. Therefore, the thicknesses of the side of the connecting circuit boards 200 and the side of the composite circuit boards 300 of the display devices are substantially the same, so as to prevent COF from peeling off from the display panel 100 due to the lack of support and improve the reliability of the display device. By adjusting the thickness of the protective housing of the transient suppression diode 210, the maximum thickness of the connecting circuit board 200 can be adjusted. On the other hand, the transient suppression diode 210 can also be connected to a circuit in the display device. When the display device is impacted by electrostatic discharge (ESD), the high impedance between the two poles of the transient suppression diode 210 becomes low impedance, to absorb surge power, and clamp the voltage between the two poles to a predetermined value, such the precision devices in the restriction device is effectively protected to prevent the precision devices from being damaged by surge pulses, and the reliability of the display device is further improved.

In the technical solution of the present disclosure, the display device includes the display panel 100, the connecting circuit board 200, the composite circuit board 300, and the flexible circuit unit 400, the connecting circuit board 200 is defined along the extending direction of the board surface of the display panel 100, and the connecting circuit board 200 includes the main body and the transient suppression diode 210 defined on the main body. The composite circuit board 300 is defined along the extending direction of the board surface of the display panel 100; At least a part of the flexible circuit units 400 connect between the display panel 100 and the main body, and at least another part of the flexible circuit units 400 connect between the display panel 100 and the composite circuit board 300. The absolute value of the difference between the maximum thickness of the connecting circuit board 200 and the maximum thickness of the composite circuit board 300 is less than or equal to the first preset thickness. The flexible circuit unit 400 and the control circuit on the composite circuit board 300 work together to drive the display panel 100 to normally display, while the connection circuit on the composite circuit board 300 and the connecting circuit board 200 are used to realize at least partial electrical connection in the display device. On the one hand, the transient suppression diode 210 increases the thickness of the connecting circuit board 200 so that the absolute value of the difference between the maximum thickness of the connecting circuit board 200 and the maximum thickness of the composite circuit board 300 is less than or equal to the first preset thickness. Furthermore, the height difference between the flexible circuit unit 400 connected between the display panel 100 and the main body, and the flexible circuit unit 400 connected between the display panel 100 and the composite circuit board 300 during boxing is reduced, so that the display panel 100, the connecting circuit board 200, and the composite circuit board 300 respectively provide support for the corresponding flexible circuit units 400, thereby avoiding the peeling of the flexible circuit unit 400 relative to the display panel 100, and improving the reliability of the display device.

Furthermore, taking the liquid crystal display device as an example, the display panel 100 includes a first substrate, a second substrate, and liquid crystals filled between the first substrate and the second substrate. The flexible circuit unit 400 includes a liquid crystal deflection control circuit. The composite circuit board 300 includes a timing control circuit. The display device further includes a flat cable 500 connected between the connecting circuit board 200 and the composite circuit board 300. The liquid crystal deflection control circuit and the timing control circuit jointly control the deflection of the liquid crystals between the first substrate and the second substrate, so as to control the display of images, and the flat cable 500 connected between the connecting circuit board 200 and the composite circuit board 300 realizes partial electrical connection in the display device to transmit corresponding electrical signals.

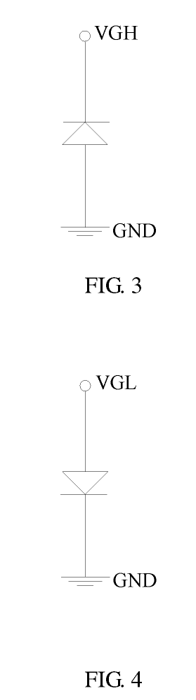

In some embodiments of the present disclosure, as shown in FIG. 3, a positive electrode of the transient suppression diode 210 connects to the ground line (GND) of the display device, and a negative electrode of the transient suppression diode 210 connects to the positive power line (VGH) of the display device. The positive power line of the display device provides a high level for driving the display panel 100. In some embodiments, under normal circumstances, the transient suppression diode 210 is reversely connected to the circuit and is in an open circuit state with high resistance. When the display device is impacted by electro-static discharge (ESD), the resistance of the transient suppression diode 210 decreases rapidly and is in the conducting state, thus realizing the function of clamping high level to protect relevant components in the display device.

In another embodiment of the present disclosure, as shown in FIG. 4, a positive electrode of the transient suppression diode 210 connects to a negative power supply line (VGL) of the display device, and a negative electrode of the transient suppression diode 210 connects to the ground line (GND) of the display device. The negative power line of the display device provides a low level for driving the display panel 100. In some embodiments, under normal circumstances, the transient suppression diode 210 is reversely connected to the circuit and is in an open circuit state with high resistance. When the display device is impacted by ESD, the resistance of the transient suppression diode 210 decreases rapidly and is in the conducting state, thus realizing the function of clamping the low level to protect relevant components in the display device.

Of course, in the present disclosure, bidirectional transient suppression diode 210 or a plurality of transient suppression diodes 210 may be provided by combining the above two embodiments to achieve common clamping of high and low levels and further improve the reliability of the display device.

In the above-described embodiments of the present disclosure, the end of the transient suppression diode 210 away from the main body has a support surface which is parallel to the board surface of the connecting circuit board 200. Through the support surface, the contact area between the transient suppression diode 210 and the main body of the adjacent connecting circuit board 200 in the stacked display devices is increased, so that the stacking of the display devices is more stable, and the connecting circuit board 200 stacked at the lower position is also prevented from being damaged due to excessive pressure.

Furthermore, the first preset thickness is less than or equal to 0.2 millimeters. The smaller the first preset thickness, the smaller the thickness difference between the connecting circuit board 200 and the composite circuit board 300 in the display device, thus making the COF more stable and improving the reliability of the display device. When the first preset thickness is less than or equal to 0.2 millimeters, the thickness difference between the connecting circuit board 200 and the composite circuit board 300, corresponding to ten display devices stacked together, is less than 2 millimeters, which can meet the normal packing and transportation requirements and avoid COF peeling.

In the above embodiments of the present disclosure, the absolute value of the difference between the maximum thickness of the display panel 100 and the maximum thickness of the connecting circuit board 200 is less than or equal to the second preset thickness. The absolute value of the difference between the maximum thickness of the display panel 100 and the maximum thickness of the composite circuit board 300 is less than or equal to the third preset thickness. Since the display panel 100 occupies a large area in the display device, by limiting the maximum thickness of the display panel 100 and the maximum thickness of the connecting circuit board 200, as well as the maximum thickness of the display panel 100 and the maximum thickness of the composite circuit board 300, the flatness of the entire display device is further improved, thereby facilitating the avoidance of COF between the display panel 100 and the connecting circuit board 200 from peeling, and COF between the display panel 100 and the composite circuit board 300 from peeling. By setting the thickness of the housing of the transient suppression diode 210 or the thicknesses of the housings of the integrated circuit chip 310 and inductor, etc., the thicknesses of the connecting circuit board 200 and the composite circuit board 300 can be adjusted to meet the above requirements.

Furthermore, the second preset thickness is less than or equal to 0.5 millimeters, and the smaller the second preset thickness, the smaller the thickness difference between the display panel 100 and the connecting circuit board 200 in the display device, thereby making the COF more stable and improving the reliability of the display device. When the second preset thickness is less than or equal to 0.5 millimeters, the thickness difference between the display panels 100 and the connecting circuit board 200, corresponding to ten display devices stacked together, is less than 5 millimeters, which can meet the normal packing and transportation requirements and avoid the peeling of COF.

Furthermore, the third preset thickness is less than or equal to 0.5 millimeters, and the smaller the third preset thickness, the smaller the thickness difference between the display panel 100 and the composite circuit board 300 in the display device, thereby making the COF more stable and improving the reliability of the display device. When the third preset thickness is less than or equal to 0.5 millimeters, the thickness difference between the display panels 100 and the composite circuit boards 300, corresponding to ten display devices stacked together, is less than 5 millimeters, which can meet the normal packing and transportation requirements and avoid the peeling of COF.

In some embodiments of the present disclosure, the connecting circuit board 200 includes one or more transient suppression diodes 210. When the connecting circuit board 200 includes one transient suppression diode 210, the transient suppression diode 210 can be defined at the center of the connecting circuit board 200 to improve the stability of the support.

Of course, the connecting circuit board 200 may also include at least two transient suppression diodes 210, the transient suppression diodes 210 are dispersedly defined on the connecting circuit board 200 to improve the stability of the support.

The foregoing description merely depicts some embodiments of the present disclosure and therefore is not intended to limit the scope of the present disclosure. An equivalent structural or flow changes made by using the content of the specification and drawings of the present disclosure, or any direct or indirect present disclosures of the disclosure on any other related fields shall all fall in the scope of the present disclosure.

What is claimed is:

1. A display device, wherein the display device comprises:
a display panel;
a connecting circuit board, the connecting circuit board is defined along an extending direction of a board surface of the display panel, and the connecting circuit board comprises a main body and a transient suppression diode defined on the main body;
a composite circuit board, the composite circuit board is defined along the extending direction of the board surface of the display panel; and
flexible circuit units, at least a part of the flexible circuit units connect between the display panel and the main body, and at least another part of the flexible circuit units connect between the display panel and the composite circuit board;
an absolute value of a difference between the maximum thickness of the connecting circuit board and the maximum thickness of the composite circuit board is less than or equal to a first preset thickness.

2. The display device according to claim 1, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

3. The display device according to claim 1, wherein a positive electrode of the transient suppression diode connects to a ground line of the display device, and a negative electrode of the transient suppression diode connects to a positive power line of the display device; or
a positive electrode of the transient suppression diode connects to a negative power line of the display device, and a negative electrode of the transient suppression diode connects to a ground line of the display device.

4. The display device according to claim 3, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

5. The display device according to claim 1, wherein an end of the transient suppression diode away from the main body comprises a support surface, the support surface is parallel to the board surface of the connecting circuit board.

6. The display device according to claim 5, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

7. the display device according to claim 1, wherein the first preset thickness is less than or equal to 0.2 millimeters.

8. The display device according to claim 7, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

9. The display device according to claim 1, wherein an absolute value of a difference between the maximum thickness of the display panel and the maximum thickness of the connecting circuit board is less than or equal to a second preset thickness; and
an absolute value of a difference between the maximum thickness of the display panel and the maximum thickness of the composite circuit board is less than or equal to a third preset thickness.

10. The display device according to claim 9, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

11. The display device according to claim 9, wherein the second preset thickness is less than or equal to 0.5 millimeters, and the third preset thickness is less than or equal to 0.5 millimeters.

12. The display device according to claim 11, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

13. The display device according to claim 1, wherein the transient suppression diode is defined at the center of the connecting circuit board.

14. The display device according to claim 13, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

15. The display device according to claim 1, wherein the connecting circuit board comprises at least two transient suppression diodes, the transient suppression diodes are dispersedly defined on the connecting circuit board.

16. The display device according to claim 15, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

17. A display device, wherein the display device comprises:
a display panel;
a connecting circuit board, the connecting circuit board is defined along an extending direction of a board surface of the display panel, and the connecting circuit board comprises a main body and a transient suppression diode defined on the main body, a positive electrode of the transient suppression diode connects to a ground line of the display device, and a negative electrode of the transient suppression diode connects to a positive power line of the display device; or a positive electrode of the transient suppression diode connects to a negative power line of the display device, and a negative electrode of the transient suppression diode connects to a ground line of the display device, an end of the transient suppression diode away from the main body comprises a support surface, the support surface is parallel to the board surface of the connecting circuit board;
a composite circuit board, the composite circuit board is defined along the extending direction of the board surface of the display panel; and
flexible circuit units, at least a part of the flexible circuit units connect between the display panel and the main body, and at least another part of the flexible circuit units connect between the display panel and the composite circuit board;
an absolute value of a difference between the maximum thickness of the connecting circuit board and the maximum thickness of the composite circuit board is less than or equal to a first preset thickness, an absolute value of a difference between the maximum thickness of the display panel and the maximum thickness of the connecting circuit board is less than or equal to a second preset thickness; and an absolute value of a difference between the maximum thickness of the display panel and the maximum thickness of the composite circuit board is less than or equal to a third preset thickness.

18. The display device according to claim 17, wherein the display panel comprises a first substrate, a second substrate, and liquid crystals filled between the first substrate and the second substrate;
the flexible circuit unit comprises a liquid crystal deflection control circuit;
the composite circuit board comprises a timing control circuit;
the display device further comprises a flat cable, and the flat cable connects between the connecting circuit board and the composite circuit board.

19. the display device of claim 17, wherein the first preset thickness is less than or equal to 0.2 millimeters.

20. The display device of claim 17, wherein the second preset thickness is less than or equal to 0.5 millimeters, and the third preset thickness is less than or equal to 0.5 millimeters.
